(19) United States
(12) Patent Application Publication
(10) Pub. No.: US 2026/0255488 A1
(43) Pub. Date: Aug. 27, 2026

(54) TERMINAL DEVICE

(71) Applicant: Honor Device Co., Ltd., Shenzhen (CN)

(72) Inventors: Yulong Zhang, Shenzhen (CN); Kaiqiang Wang, Shenzhen (CN); Qing Dong, Shenzhen (CN)

(21) Appl. No.: 18/881,978

(22) PCT Filed: Aug. 11, 2023
(86) PCT No.: PCT/CN2023/112695

§ 371 Date: Jan. 7, 2025

(30) Foreign Application Priority Data
Dec. 29, 2022 (CN) 202211709593.X

(51) Int. Cl. H05K 1/14; H05K 1/11

(52) U.S. Cl. CPC H05K 1/147; H05K 1/115; H05K 1/118; H05K 2201/10037

(57) ABSTRACT

This application relates to the field of electronic product technologies, and in particular, to a terminal device. A first component group in the terminal device includes at least one selected from a processor chip, a baseband chip, a radio frequency assembly, and a camera assembly. One end of a flexible printed circuit board is connected to a first circuit board of the first component group, and a first branch and a second branch are disposed on the other end of the flexible printed circuit board. The second component group and the third component group are respectively electrically connected to the first branch and the second branch. I

[symbol]

### CROSS-REFERENCE TO RELATED APPLICATIONS

This application is a national stage of International Application No. PCT/CN2023/112695, filed on Aug. 11, 2023, which claims priority to Chinese Patent Application No. 202211709593.X, filed on Dec. 29, 2022, both of which are incorporated herein by reference in their entireties.

### TECHNICAL FIELD

This application relates to the field of electronic product technologies, and in particular, to a terminal device.

### BACKGROUND

As a usage rate of using a terminal device such as a mobile phone or a tablet by a user increases, use stability of the terminal device becomes an increasingly important evaluation indicator. However, in a use process of some terminal devices, phenomena such as a crash and automatic shutdown occur sometimes, which reduces use stability of the terminal devices.

### SUMMARY

This application provides a terminal device, to help improve use stability.

According to a first aspect, this application provides a terminal device. The terminal device includes a first component group, a second component group, a third component group, and a flexible printed circuit board, the first component group includes a first circuit board, and at least one selected from a processor chip, a baseband chip, a radio frequency assembly, and a camera assembly is disposed on the first circuit board; one end of the flexible printed circuit board is connected to the first circuit board, and a first branch and a second branch are disposed on the other end of the flexible printed circuit board; the second component group is electrically connected to the first branch; and the third component group is electrically connected to the second branch.

The one end of the flexible printed circuit board is connected to the first circuit board, the second component group is electrically connected to the first branch at the other end of the flexible printed circuit board, and the third component group is electrically connected to the second branch at the other end of the flexible printed circuit board, so that the integrated flexible printed circuit board is formed, and a quantity of flexible printed circuit boards is reduced, thereby helping reduce costs. In addition, the reduction in the quantity of flexible printed circuit boards helps simplify a structural arrangement in the terminal device, helps reduce a failure rate of the flexible printed circuit board, reduces assembling interference to a battery, helps improve connection stability of the battery and stability of an output voltage, helps reduce a possibility of a crash and automatic shutdown of the terminal device, and helps improve use stability of the terminal device.

In a possible implementation, the two ends of the flexible printed circuit board are respectively connected to the first component group and the second component group, and the first branch is disposed on an end portion of the flexible printed circuit board facing away from the first component group; the terminal device has a first direction and a second direction, the first direction is set as a direction from the first component group to the second component group, the first direction intersects the second direction, and the second direction is set to be parallel to a plane of the flexible printed circuit board; and in the second direction, the second branch is disposed between two side edges of the flexible printed circuit board or the second branch is disposed on a side edge of the flexible printed circuit board.

In another possible implementation, a first through structure is provided on the flexible printed circuit board, and the second branch is disposed on a sidewall of the first through structure.

In another possible implementation, when the second branch is disposed between the two side edges of the flexible printed circuit board in the second direction, the first through structure is set as a through hole; or when the second branch is disposed on the side edge of the flexible printed circuit board, the first through structure is set as a first notch.

In another possible implementation, the terminal device further includes a communication card mounting portion; and when the second branch is disposed on the side edge of the flexible printed circuit board in the second direction, the communication card mounting portion is disposed on a side of the flexible printed circuit board facing away from the second branch.

In another possible implementation, the terminal device further includes a connection frame body, and the connection frame body has a first side and a second side that are provided opposite to each other; the second component group is disposed on the first side, and both the first component group and the third component group are disposed on the second side; and a second through structure and a third through structure are provided on the connection frame body, one end of the flexible printed circuit board passes through the second through structure from the first side to be electrically connected to the first component group, and the second branch passes through the third through structure from the first side to be electrically connected to the third component group.

In another possible implementation, the terminal device further includes a battery and a first bonding layer, and the battery is disposed on the second side; the first component group is spaced apart from the third component group, and both the battery and the first bonding layer are disposed between the first component group and the third component group; the first bonding layer is disposed between the battery and the connection frame body, and two sides of the first bonding layer are respectively bonded to the battery and the connection frame body; and a second notch is provided on a side of the first bonding layer facing the first component group, and the second notch communicates with the second through structure.

In another possible implementation, the connection frame body includes a connection plate, and a first vertical plate and a second vertical plate spaced apart from each other are disposed on a second side of the connection plate; the first component group is disposed on a side of the first vertical plate facing away from the second vertical plate, both the battery and the first bonding layer are disposed between the first vertical plate and the second vertical plate, and the third component group is disposed on a side of the second vertical plate facing away from the first vertical plate; and the second through structure is provided on the connection plate, and the second through structure is provided between the first vertical plate and the second vertical plate, or the second through structure is provided on the side of the first vertical plate facing away from the second vertical plate.

In another possible implementation, when the second through structure is provided between the first vertical plate and the second vertical plate, a distance from the second through structure to the first vertical plate is less than a distance from the second through structure to the second vertical plate.

In another possible implementation, when the second through structure is provided between the first vertical plate and the second vertical plate, a groove is provided on the connection plate, the groove extends in the direction from the first component group to the second component group, and an end portion of the groove is connected to the second through structure; and in the direction from the first component group to the second component group, a part of the flexible printed circuit board is accommodated in the groove.

In another possible implementation, the terminal device further includes a second bonding layer, the second bonding layer is disposed in the groove, and two sides of the second bonding layer are respectively bonded to the flexible printed circuit board and a wall surface of the groove.

In another possible implementation, a third notch is provided on a side of the first vertical plate facing away from the connection plate, and the flexible printed circuit board is at least partially accommodated in the third notch in a thickness direction.

In another possible implementation, a first bent portion, a second bent portion, and a third bent portion are provided on the flexible printed circuit board, and the first bent portion, the second bent portion, and the third bent portion are arranged in the direction from the first component group to the second component group; and there is a first included angle between a part of the flexible printed circuit board on a side of the first bent portion facing away from the second bent portion and a plate plane of the connection plate, there is a second included angle between a plate plane of the first vertical plate and a part of the flexible printed circuit board between the first bent portion and the second bent portion, there is a third included angle between a part of the flexible printed circuit board on a side of the third bent portion facing away from the second bent portion and the plate plane of the connection plate, and the first included angle, the second included angle, and the third included angle are all set to be greater than or equal to 0 degrees and less than 90 degrees.

In another possible implementation, the flexible printed circuit board includes a main body section, two ends of the main body section are respectively connected to the first component group and the second component group, and the first branch is disposed on an end portion of the main body section facing away from the first component group; and the third through structure is provided on the connection plate, and the third through structure is provided on a side of the second vertical plate facing away from the first vertical plate, or the third through structure is provided between the first vertical plate and the second vertical plate, and a distance from the third through structure to the second vertical plate is less than a distance from the third through structure to the first vertical plate.

In another possible implementation, a fourth bent portion and a fifth bent portion are provided on the flexible printed circuit board, two ends of the fourth bent portion are respectively connected to the main body section and the second branch, and the fifth bent portion is provided on the second branch; and there is a fourth included angle between a plate plane of the second vertical plate and a part of the second branch between the fourth bent portion and the fifth bent portion, there is a fifth included angle between a part of the second branch on a side of the fifth bent portion facing away from the fourth bent portion and a plate plane of the connection plate, and both the fourth included angle and the fifth included angle are set to be greater than or equal to 0 degrees and less than 90 degrees.

In another possible implementation, the third component group includes a second circuit board; and when the third through structure is provided on the side of the second vertical plate facing away from the first vertical plate, a fourth notch is provided on an edge of the second circuit board, and the second branch passes through the fourth notch to be connected to the second circuit board.

In another possible implementation, a connection ring is disposed at the second through structure or the third through structure, an outer side of the connection ring is connected to the second through structure or the third through structure, and an inner side of the connection ring abuts against the flexible printed circuit board.

In another possible implementation, the connection frame body includes a connection plate, and both the second through structure and the third through structure are provided on the connection plate; and a first ring plate and a second ring plate are respectively disposed at two ends of the outer side of the connection ring, two sides of the connection plate respectively abut against the first ring plate and the second ring plate, and there is a movable gap between and a wall surface of the second through structure or a wall surface of the third through structure and a part of the connection ring between the first ring plate and the second ring plate.

In another possible implementation, a first rib plate is disposed on one side of an inner side surface of the connection ring, and a second rib plate is disposed on the other side of the inner side surface of the connection ring; and in an axial direction of the connection ring, a projection of the first rib plate and a projection of the second rib plate at least partially overlap, and two sides of the flexible printed circuit board respectively abut against the first rib plate and the second rib plate.

In another possible implementation, the flexible printed circuit board has a sixth bent portion, a sixth included angle is set between each of parts of the flexible printed circuit board on two sides of the sixth bent portion and the axial direction of the connection ring, and the sixth included angle is greater than or equal to 0 degrees and less than 90 degrees; and the parts of the flexible printed circuit board on the two sides of the sixth bent portion are respectively configured to abut against an end portion of the first rib plate and an end portion of the second rib plate.

In another possible implementation, there is a first accommodating gap between an end portion of the first rib plate and the inner side surface of the connection ring, a width of the first accommodating gap is set in a direction in which the end portion of the first rib plate, the flexible printed circuit board, and the inner side surface of the connection ring are sequentially arranged, and the width of the first accommodating gap is greater than or equal to a thickness of the flexible printed circuit board; and/or there is a second accommodating gap between an end portion of the second rib plate and the inner side surface of the connection ring, a width of the second accommodating gap is set in a direction in which the end portion of the second rib plate, the flexible printed circuit board, and the inner side surface of the connection ring are sequentially arranged, and the width of the second accommodating gap is greater than or equal to the thickness of the flexible printed circuit board.

In another possible implementation, the second component group is set as a display screen assembly; and the third component group includes a second circuit board, and at least one of a speaker, a motor, and a data interface is disposed on the second circuit board.

### BRIEF DESCRIPTION OF THE DRAWINGS

FIG. 1 is an exploded view of an embodiment of a terminal device in a forming process of this application;

FIG. 2 is a front view of an embodiment of a terminal device in a forming process of this application;

FIG. 3 is a cross-sectional view at an M-M location in FIG. 2;

FIG. 4 is an exploded view of an embodiment of a terminal device according to this application;

FIG. 5 is a three-dimensional view of a flexible printed circuit board in an embodiment of a terminal device according to this application;

FIG. 6 is a front view of an embodiment of a terminal device according to this application;

FIG. 7 is a cross-sectional view at an A1-A1 location in FIG. 6;

FIG. 8 is a partial enlarged view at A2 in FIG. 7;

FIG. 9 is a three-dimensional view of a connection frame body in an embodiment of a terminal device according to this application;

FIG. 10 is a front view of a connection frame body in an embodiment of a terminal device according to this application;

FIG. 11 is a cross-sectional view at an A3-A3 location in FIG. 10;

FIG. 12 is a schematic diagram in which a first component group is spaced apart from a third component group according to an embodiment of this application;

FIG. 13 is an exploded view of another embodiment of a terminal device according to this application;

FIG. 14 is a three-dimensional view of a flexible printed circuit board in another embodiment of a terminal device according to this application;

FIG. 15 is a front view of another embodiment of a terminal device according to this application;

FIG. 16 is a cross-sectional view at a B1-B1 location in FIG. 15;

FIG. 17 is a cross-sectional view at a B2-B2 location in FIG. 15;

FIG. 18 is a three-dimensional view of a connection frame body in another embodiment of a terminal device according to this application;

FIG. 19 is a front view of a connection frame body in another embodiment of a terminal device according to this application;

FIG. 20 is a cross-sectional view at a B3-B3 location in FIG. 19;

FIG. 21 is a schematic diagram in which a first component group is spaced apart from a third component group according to another embodiment of this application;

FIG. 22 is a front view of a connection ring in still another embodiment of a terminal device according to this application;

FIG. 23 is a schematic diagram of mounting a connection ring in still another embodiment of a terminal device according to this application; and

FIG. 24 is a schematic diagram of a flexible printed circuit board in still another embodiment of a terminal device according to this application.

### DETAILED DESCRIPTION OF ILLUSTRATIVE EMBODIMENTS

The terms “first”, “second”, “third”, and the like in the specification, claims, and accompanying drawings of this application are used to distinguish between different objects, but are not used to limit a specific sequence.

In the embodiments of this application, words such as “example” or “for example” are used to represent giving an example, an illustration, or a description. Any embodiment or design solution described as “example” or “for example” in the embodiments of this application should not be explained as being preferred or advantageous over other embodiments or design solutions. Exactly, use of the words such as “example” or “for example” is intended to present related concepts in a specific manner.

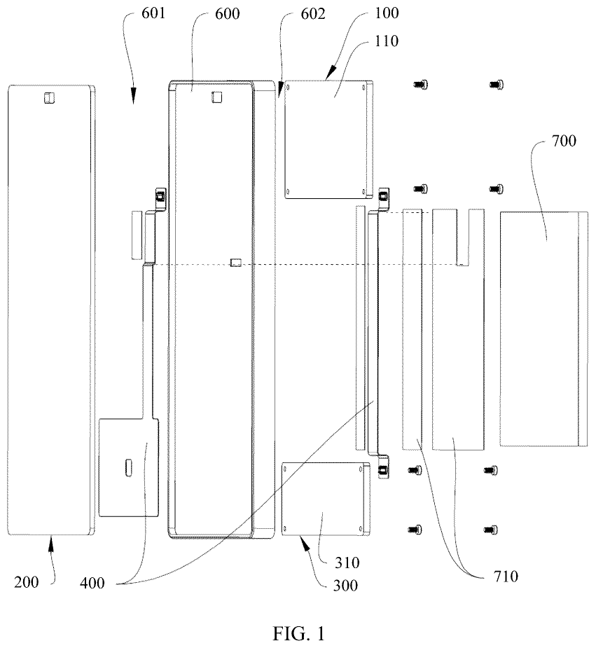

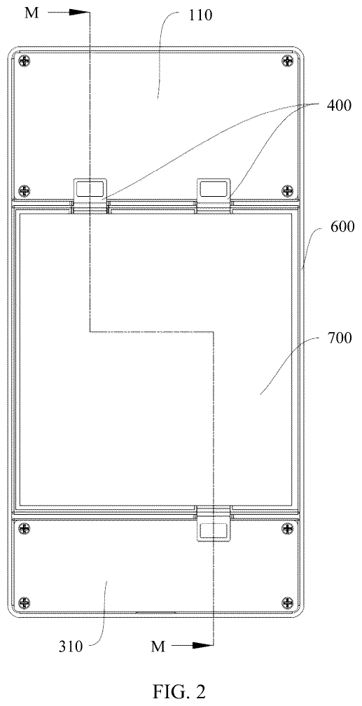

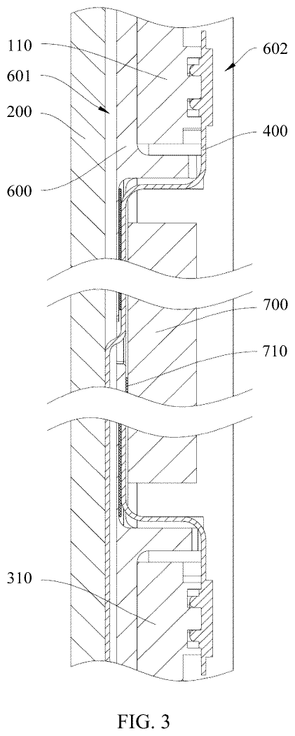

In a forming process of this application, a terminal device shown in FIG. 1 to FIG. 3 is formed. The terminal device includes a connection frame body 600, and the connection frame body 600 has a first side 601 (a left side in FIG. 1) and a second side 602 (a right side in FIG. 1) that are provided opposite to each other. A second component group 200 (which may be specifically set as a display screen assembly) is disposed on the first side 601. Both a first component group 100 (which may specifically include a first circuit board 110, where at least one selected from a processor chip, a baseband chip, a radio frequency assembly, and a camera assembly is disposed on the first circuit board 110, and in this case, the first circuit board 110 may be referred to as a mainboard) and a third component group 300 (which may specifically include a second circuit board 310, where at least one of a speaker, a motor, and a data interface is disposed on the second circuit board 310, and in this case, the second circuit board 310 may be referred to as a sub-board) are disposed on the second side 602.

The terminal device includes two independently disposed flexible printed circuit boards 400, the flexible printed circuit board 400 is an FPC (Flexible printed circuit board), and the flexible printed circuit board 400 includes a substrate and a circuit embedded in the substrate. One end of one of the flexible printed circuit boards 400 is connected to the first circuit board 110, and the other end thereof is connected to the second component group 200 after passing through the connection frame body 600. One end of the other flexible printed circuit board 400 is connected to the first circuit board 110, and the other end thereof is connected to the third component group 300. In this case, both a battery 700 and a corresponding first bonding layer 710 are disposed on the second side 602. A researcher of this application has found that one of reasons for low use stability caused by a crash or automatic shutdown of the terminal device is as follows: Because of a relatively large quantity of flexible printed circuit boards 400, a structural arrangement in the terminal device is relatively complex, the foregoing two flexible printed circuit boards 400 cause assembling interference to the battery 700, the first bonding layer 710 corresponding to the battery 700 is forcibly divided into two parts, and consequently, a bonding area of the battery 700 is reduced, and a bonding effect of the battery 700 is weakened. This degrades connection stability of the battery and stability of an output voltage.

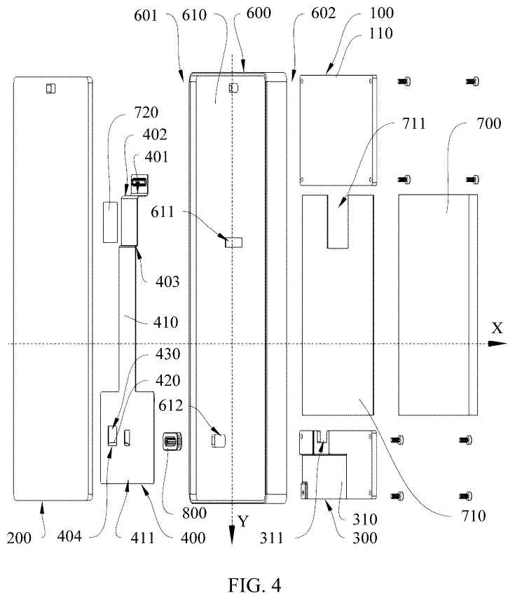

Therefore, this application provides a terminal device, and the terminal device may be set as a mobile phone, a tablet, an electronic watch, or the like. Referring to FIG. 4, the terminal device includes a first component group 100, a second component group 200, a third component group 300, and a flexible printed circuit board 400. The first component group 100 includes a first circuit board 110, and at least one selected from a processor chip, a baseband chip, a radio frequency assembly, and a camera assembly is disposed on the first circuit board 110. In this case, the first circuit board 110 may be referred to as a mainboard. The second component group 200 may be set as a display screen assembly. The third component group 300 may be set to include a second circuit board 310, and at least one of a speaker, a motor, and a data interface is disposed on the second circuit board 310. In this case, the second circuit board 310 may be referred to as a sub-board.

Referring to FIG. 4, the terminal device has a first direction and a second direction, the first direction is set as a direction from the first component group 100 to the second component group 200, the first direction intersects the second direction, and the second direction is set to be parallel to a plane of the flexible printed circuit board 400. For the first direction, refer to a Y direction in FIG. 4. For the second direction, refer to an X direction in FIG. 4.

Referring to FIG. 4 to FIG. 7, one end of the flexible printed circuit board 400 is connected to the first circuit board 110, and a first branch 411 and a second branch 420 are disposed on the other end of the flexible printed circuit board 400. The second component group 200 is electrically connected to the first branch 411. The third component group 300 is electrically connected to the second branch 420. The flexible printed circuit board 400 may be specifically connected to the first circuit board 110, the second component group 200, and the second circuit board 310 of the third component group 300 by using a BTB connector.

In this technical solution, the one end of the flexible printed circuit board 400 is connected to the first circuit board 110, the second component group 200 is electrically connected to the first branch 411 at the other end of the flexible printed circuit board 400, and the third component group 300 is electrically connected to the second branch 420 at the other end of the flexible printed circuit board 400, so that the integrated flexible printed circuit board 400 is formed, and a quantity of flexible printed circuit boards 400 is reduced, thereby helping reduce costs. In addition, the reduction in the quantity of flexible printed circuit boards 400 helps simplify a structural arrangement in the terminal device, helps reduce a failure rate of the flexible printed circuit board, reduces assembling interference to the battery 700, helps improve connection stability of the battery 700 and stability of an output voltage, helps reduce a possibility of a crash and automatic shutdown of the terminal device, and helps improve use stability of the terminal device.

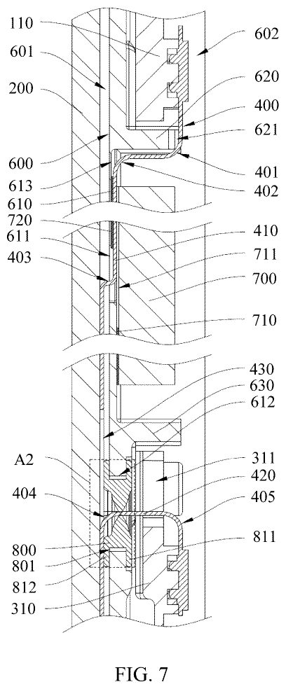

Referring to FIG. 7, the two ends of the flexible printed circuit board 400 may be set to be respectively connected to the first component group 100 and the second component group 200, and the first branch 411 is disposed on an end portion of the flexible printed circuit board 400 facing away from the first component group 100 (as shown in a lower part of FIG. 7).

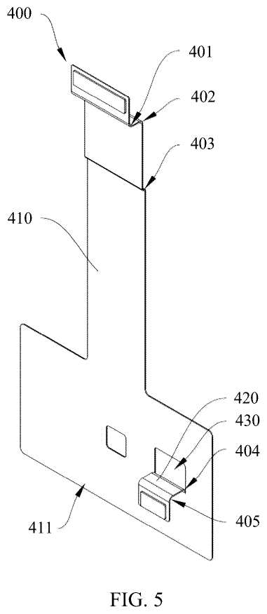

Specifically, with reference to FIG. 5, the flexible printed circuit board 400 includes a main body section 410, two ends of the main body section 410 are respectively connected to the first component group 100 and the second component group 200, and the first branch 411 is disposed on an end portion of the main body section 410 facing away from the first component group 100. Referring to FIG. 5, in the second direction, the second branch 420 is disposed between two side edges of the flexible printed circuit board 400, a first through structure 430 is provided on the flexible printed circuit board 400, the first through structure 430 is provided on the main body section 410, and the second branch 420 is disposed on a sidewall of the first through structure 430, that is, the second branch 420 extends from the sidewall of the first through structure 430. In this case, the first through structure 430 may be set as a through hole. Certainly, the first through structure 430 may alternatively be set as a notch. In this case, the second branch 420 may be disposed on a side edge (a lower side in the figure) of the flexible printed circuit board 400 in the first direction.

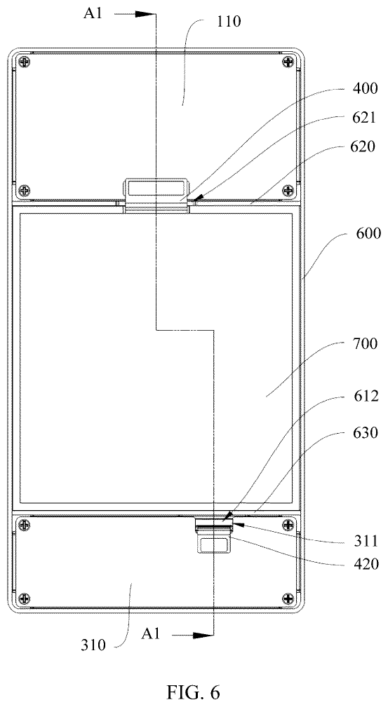

Referring to FIG. 4, FIG. 6, and FIG. 7, the terminal device further includes a connection frame body 600. The connection frame body may be set as a middle frame of the terminal device. The connection frame body 600 has a first side 601 (a left side in FIG. 7) and a second side 602 (a right side in FIG. 7) that are provided opposite to each other. The second component group 200 is disposed on the first side 601, and both the first component group 100 and the third component group 300 are disposed on the second side 602. A second through structure 611 and a third through structure 612 are provided on the connection frame body 600, and the second through structure 611 and the third through structure 612 each may be set as a through hole or a notch. This is not limited in this embodiment. One end (an upper end in the figure) of the flexible printed circuit board 400 passes through the second through structure 611 from the first side 601 to be electrically connected to the first component group 100, and the second branch 420 passes through the third through structure 612 from the first side 601 to be electrically connected to the third component group 300. Correspondingly, the terminal device further includes the battery 700 and the first bonding layer 710, and the first bonding layer 710 may be specifically set as a back adhesive or the like. Both the battery 700 and the first bonding layer 710 are disposed on the second side 602. The first component group 100 is spaced apart from the third component group 300, and both the battery 700 and the first bonding layer 710 are disposed between the first component group 100 and the third component group 300. The first bonding layer 710 is disposed between the battery 700 and the connection frame body 600, and two sides of the first bonding layer 710 are respectively bonded to the battery 700 and the connection frame body 600. A second notch 711 is provided on a side of the first bonding layer 710 facing the first component group 100, and the second notch 711 communicates with the second through structure 611. Therefore, the first bonding layer 710 is prevented, by using the second notch 711, from being bonded to the flexible printed circuit board 400 projecting from the second through structure 611.

In this case, a part of the flexible printed circuit board 400 on the first side 601 (the left side in FIG. 7) of the connection frame body can reduce an area of the second notch 711, and increase a bonding area of the first bonding layer 710 to the battery 700, thereby improving bonding stability of the battery 700, connection stability of the battery, and stability of an output voltage, further reducing a possibility of a crash and automatic shutdown of the terminal device, and further improving use stability of the terminal device.

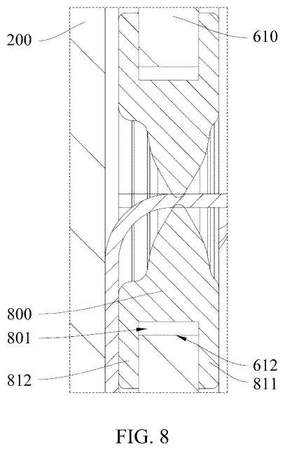

Referring to FIG. 7 and FIG. 8, the connection frame body 600 includes a connection plate 610, and both the second through structure 611 and the third through structure 612 are provided on the connection plate 610. A connection ring 800 is disposed at the third through structure 612, and the connection ring 800 may be specifically made of a material with elasticity, such as rubber. An outer side of the connection ring 800 is connected to the third through structure 612, and an inner side of the connection ring 800 abuts against the flexible printed circuit board 400. Usually, because the terminal device has an insertion/removal structure such as a card tray, there is a risk that liquid and steam are introduced from the insertion/removal structure such as the card tray. In this case, the connection ring 800 can reduce smoothness of flowing of the introduced liquid and the introduced steam along the flexible printed circuit board 400, and alleviate damage to the terminal device caused by the introduced liquid and the introduced steam. Further, the inner side of the connection ring 800 may be set to be in interference fit with the flexible printed circuit board 400, to further improve a blocking capability for the introduced liquid and the introduced steam, and further alleviate damage to the terminal device caused by the introduced liquid and the introduced steam.

Referring to FIG. 8, a first ring plate 811 and a second ring plate 812 are respectively disposed at two ends (left and right ends in FIG. 8) on the outer side of the connection ring 800, and two sides of the connection plate 610 respectively abut against the first ring plate 811 and the second ring plate 812. There is a movable gap 801 between a wall surface of the third through structure 612 and a part of the connection ring 800 between the first ring plate 811 and the second ring plate 812, and the movable gap 801 can enable the connection ring 800 to be more smoothly mounted in the third through structure 612. In addition, the third through structure 612 is usually formed in a manner of mechanical processing, injection molding, casting, or the like, and there may be a burr on the wall surface of the third through structure 612. The movable gap 801 can further reduce a possibility of piercing the connection ring 800 by the burr on the wall surface of the third through structure 612, and reduce a failure risk of the connection ring 800.

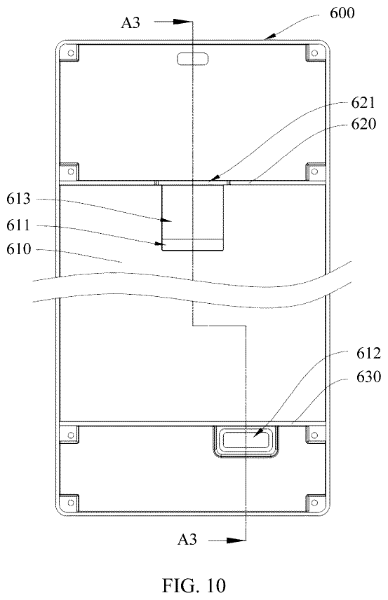

Referring to FIG. 7 and FIG. 9 to FIG. 11, a first vertical plate 620 and a second vertical plate 630 spaced apart from each other are disposed on the second side 602 of the connection plate 610, that is, the first vertical plate 620 and the second vertical plate 630 are in a vertical state relative to the connection plate 610. The first component group 100 is disposed on a side of the first vertical plate 620 facing away from the second vertical plate 630 (for example, disposed on an upper side in FIG. 7), both the battery 700 and the first bonding layer 710 are disposed between the first vertical plate 620 and the second vertical plate 630, and the third component group 300 (including the second circuit board 310) is disposed on a side of the second vertical plate 630 facing away from the first vertical plate 620 (for example, disposed on a lower side in FIG. 7). The second through structure 611 may be provided between the first vertical plate 620 and the second vertical plate 630 (in this case, a distance from the second through structure 611 to the first vertical plate 620 may be further set to be less than a distance from the second through structure 611 to the second vertical plate 630, that is, the second through structure 611 is closer to the first vertical plate 620). Certainly, the second through structure 611 may alternatively be provided on the side of the first vertical plate 620 facing away from the second vertical plate 630. This is not limited in this embodiment. The third through structure 612 is provided on the side of the second vertical plate 630 facing away from the first vertical plate 620 (for example, provided on the lower side in FIG. 7). Alternatively, the third through structure 612 is provided between the first vertical plate 620 and the second vertical plate 630, and a distance from the third through structure 612 to the second vertical plate 630 is less than a distance from the third through structure 612 to the first vertical plate 620 (that is, the third through structure 612 is closer to the second vertical plate 630). This is not limited in this embodiment.

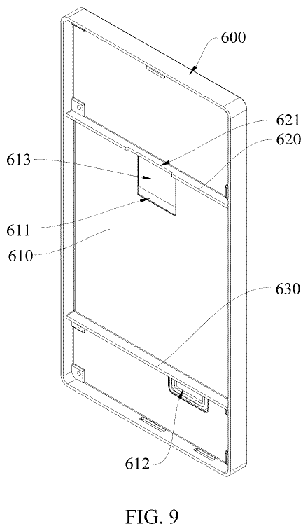

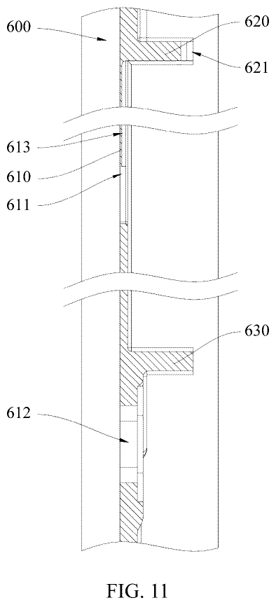

In addition, referring to FIG. 7, FIG. 9, and FIG. 11, while the second through structure 611 is provided between the first vertical plate 620 and the second vertical plate 630, a groove 613 is provided on the connection plate 610, the groove 613 extends in the direction from the first component group 100 to the second component group 200 (in a vertical direction in the figure), and an end portion of the groove 613 is connected to the second through structure 611.

In the direction from the first component group 100 to the second component group 200, a part of the flexible printed circuit board 400 is accommodated in the groove 613. The groove 613 can reduce a total thickness of the part of the flexible printed circuit board 400 accommodated in the groove 613 and the connection plate 610, thereby reducing the overall thickness of the terminal device.

To make a connection of a part of the flexible printed circuit board 400 on the second side 602 of the connection frame body 600 more stable, referring to FIG. 7, the terminal device further includes a second bonding layer 720, and the second bonding layer 720 may be set as a back adhesive. The second bonding layer 720 is disposed in the groove 613, and two sides of the second bonding layer 720 are respectively bonded to the flexible printed circuit board 400 and a wall surface of the groove 613. In this case, the second bonding layer 720 is disposed in the groove 613, which also helps reduce the overall thickness of the terminal device by using the groove 613.

Referring to FIG. 7 and FIG. 9 to FIG. 11, a third notch 621 is provided on a side of the first vertical plate 620 facing away from the connection plate 610, and the flexible printed circuit board 400 is at least partially accommodated in the third notch 621 in a thickness direction. The third notch 621 can alleviate scratch damage to the flexible printed circuit board 400, and reduce a stacking thickness of the third notch 621 and the flexible printed circuit board 400, which helps reduce the overall thickness of the terminal device. In addition, a part of the first vertical plate 620 outside the third notch 621 can have a relatively high height, which helps improve structural strength of the first vertical plate 620 and the connection frame body 600.

When the first vertical plate 620 and the second vertical plate 630 are disposed, referring to FIG. 7, a first bent portion 401, a second bent portion 402, and a third bent portion 403 are provided on the flexible printed circuit board 400. The first bent portion 401, the second bent portion 402, and the third bent portion 403 are arranged in the direction from the first component group 100 to the second component group 200. The first bent portion 401 and the second bent portion 402 may be set as L-shaped bends, and the third bend 403 may be set as a Z-shaped bend. There is a first included angle between a part (an upper part in FIG. 7) of the flexible printed circuit board 400 on a side of the first bent portion 401 facing away from the second bent portion 402 and a plate plane of the connection plate 610. For example, the first included angle is 0 degrees, and the part is set to be parallel to the plate plane of the connection plate 610 as a whole. There is a second included angle between a plate plane of the first vertical plate 620 and a part of the flexible printed circuit board 400 between the first bent portion 401 and the second bent portion 402. For example, the second included angle is 0 degrees, and the part is set to be parallel to the plate plane of the first vertical plate 620 as a whole. There is a third included angle between a part of the flexible printed circuit board 400 on a side of the third bent portion 403 facing away from the second bent portion 402 and the plate plane of the connection plate 610. For example, the third included angle is 0 degrees, and the part is set to be parallel to the plate plane of the connection plate 610 as a whole. That is, the first included angle, the second included angle, and the third included angle are set to be greater than or equal to 0 degrees and less than 90 degrees, for example, 0 degrees, 10 degrees, 20 degrees, 45 degrees, or 60 degrees. This is not limited in this embodiment.

Still referring to FIG. 7, a fourth bent portion 404 and a fifth bent portion 405 are provided on the flexible printed circuit board 400, and the fourth bent portion 404 and the fifth bent portion 405 may be set as L-shaped bends. Two ends of the fourth bent portion 404 are respectively connected to the main body section 410 and the second branch 420, and the fifth bent portion 405 is provided on the second branch 420. There is a fourth included angle between a plate plane of the second vertical plate 630 and a part of the second branch 420 between the fourth bent portion 404 and the fifth bent portion 405. For example, the fourth included angle is 0 degrees, and the part is set to be parallel to the plate plane of the second vertical plate 630 as a whole. There is a fifth included angle between a part (a lower right part in FIG. 7) of the second branch 420 on a side of the fifth bent portion 405 facing away from the fourth bent portion 404 and the plate plane of the connection plate 610. For example, the fifth included angle is 0 degrees, and the part is set to be parallel to the plate plane of the connection plate 610 as a whole. That is, both the fourth included angle and the fifth included angle are set to be greater than or equal to 0 degrees and less than 90 degrees, for example, 0 degrees, 10 degrees, 20 degrees, 45 degrees, or 60 degrees. This is not limited in this embodiment.

Referring to FIG. 12, a fourth notch 311 is provided on an edge of the second circuit board 310, and the second branch 420 passes through the fourth notch 311 to be connected to the second circuit board 310, to improve the overall compactness of the terminal device.

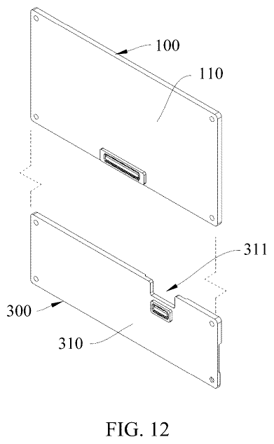

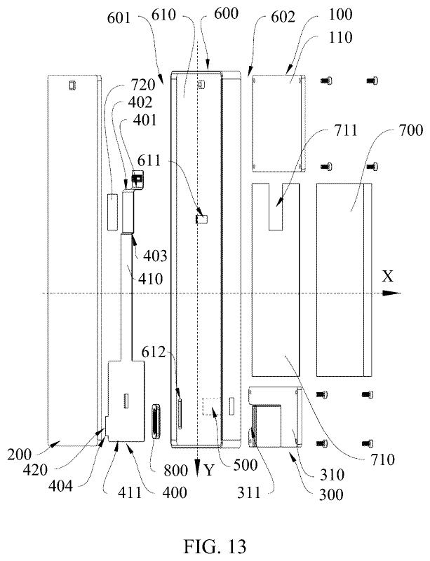

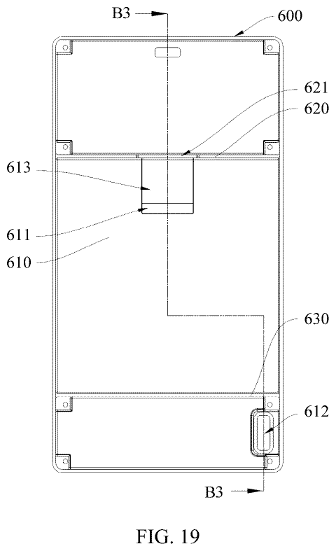

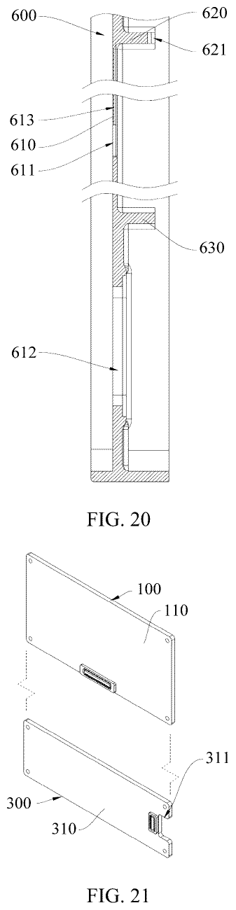

FIG. 13 to FIG. 21 show another embodiment of a terminal device in this application. Referring to FIG. 13, the terminal device includes a first component group 100, a second component group 200, a third component group 300, and a flexible printed circuit board 400. The first component group 100 includes a first circuit board 110, and at least one selected from a processor chip, a baseband chip, a radio frequency assembly, and a camera assembly is disposed on the first circuit board 110. In this case, the first circuit board 110 may be referred to as a mainboard. The second component group 200 may be set as a display screen assembly. The third component group 300 may be set to include a second circuit board 310, and at least one of a speaker, a motor, and a data interface is disposed on the second circuit board 310. In this case, the second circuit board 310 may be referred to as a sub-board.

Referring to FIG. 13, the terminal device has a first direction and a second direction, the first direction is set as a direction from the first component group 100 to the second component group 200, the first direction intersects the second direction, and the second direction is set to be parallel to a plane of the flexible printed circuit board 400. For the first direction, refer to a Y direction in FIG. 13. For the second direction, refer to an X direction in FIG. 13.

Referring to FIG. 13 to FIG. 17, one end of the flexible printed circuit board 400 is connected to the first circuit board 110, and a first branch 411 and a second branch 420 are disposed on the other end of the flexible printed circuit board 400. The second component group 200 is electrically connected to the first branch 411. The third component group 300 is electrically connected to the second branch 420. The flexible printed circuit board 400 may be specifically connected to the first circuit board 110, the second component group 200, and the second circuit board 310 of the third component group 300 by using a BTB connector.

In this technical solution, the one end of the flexible printed circuit board 400 is connected to the first circuit board 110, the second component group 200 is electrically connected to the first branch 411 at the other end of the flexible printed circuit board 400, and the third component group 300 is electrically connected to the second branch 420 at the other end of the flexible printed circuit board 400, so that the integrated flexible printed circuit board 400 is formed, and a quantity of flexible printed circuit boards 400 is reduced, thereby helping reduce costs. In addition, the reduction in the quantity of flexible printed circuit boards 400 helps simplify a structural arrangement in the terminal device, helps reduce a failure rate of the flexible printed circuit board, reduces assembling interference to a battery 700, helps improve connection stability of the battery 700 and stability of an output voltage, helps reduce a possibility of a crash and automatic shutdown of the terminal device, and helps improve use stability of the terminal device.

Referring to FIG. 13, the two ends of the flexible printed circuit board 400 may be set to be respectively connected to the first component group 100 and the second component group 200, and the first branch 411 is disposed on an end portion of the flexible printed circuit board 400 facing away from the first component group 100 (as shown in a lower part of FIG. 13).

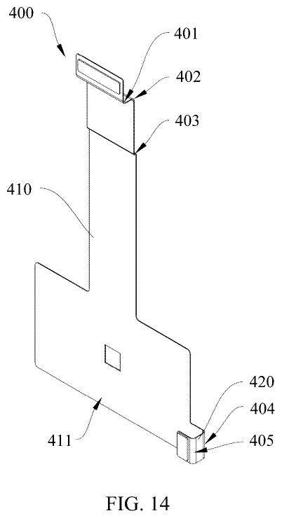

Specifically, with reference to FIG. 14, the flexible printed circuit board 400 includes a main body section 410, two ends of the main body section 410 are respectively connected to the first component group 100 and the second component group 200, and the first branch 411 is disposed on an end portion of the main body section 410 facing away from the first component group 100. In the second direction, the second branch 420 is disposed on a side edge of the flexible printed circuit board 400 (a right side edge shown in FIG. 14).

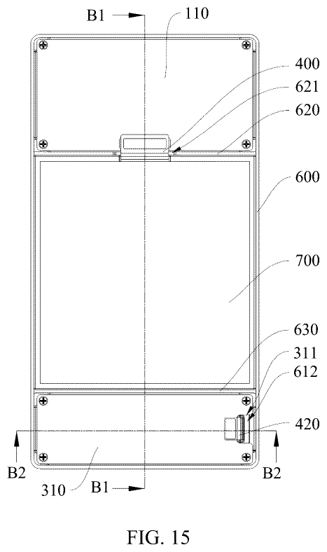

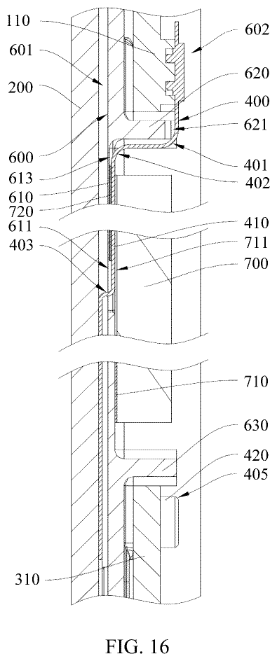

Referring to FIG. 13, FIG. 15, and FIG. 16, the terminal device further includes a connection frame body 600. The connection frame body may be set as a middle frame of the terminal device. The connection frame body 600 has a first side 601 (a left side in FIG. 16) and a second side 602 (a right side in FIG. 16) that are provided opposite to each other. The second component group 200 is disposed on the first side 601, and both the first component group 100 and the third component group 300 are disposed on the second side 602. A second through structure 611 and a third through structure 612 are provided on the connection frame body 600, and the second through structure 611 and the third through structure 612 each may be set as a through hole or a notch. This is not limited in this embodiment. One end (an upper end in the figure) of the flexible printed circuit board 400 passes through the second through structure 611 from the first side 601 to be electrically connected to the first component group 100, and the second branch 420 passes through the third through structure 612 from the first side 601 to be electrically connected to the third component group 300. Correspondingly, the terminal device further includes the battery 700 and a first bonding layer 710, and the first bonding layer 710 may be specifically set as a back adhesive or the like. Both the battery 700 and the first bonding layer 710 are disposed on the second side 602. The first component group 100 is spaced apart from the third component group 300, and both the battery 700 and the first bonding layer 710 are disposed between the first component group 100 and the third component group 300. The first bonding layer 710 is disposed between the battery 700 and the connection frame body 600, and two sides of the first bonding layer 710 are respectively bonded to the battery 700 and the connection frame body 600. A second notch 711 is provided on a side of the first bonding layer 710 facing the first component group 100, and the second notch 711 communicates with the second through structure 611. Therefore, the first bonding layer 710 is prevented, by using the second notch 711, from being bonded to the flexible printed circuit board 400 projecting from the second through structure 611.

In this case, a part of the flexible printed circuit board 400 on the first side 601 (the left side in FIG. 16) of the connection frame body can reduce an area of the second notch 711, and increase a bonding area of the first bonding layer 710 to the battery 700, thereby improving bonding stability of the battery 700, connection stability of the battery, and stability of an output voltage, further reducing a possibility of a crash and automatic shutdown of the terminal device, and further improving use stability of the terminal device.

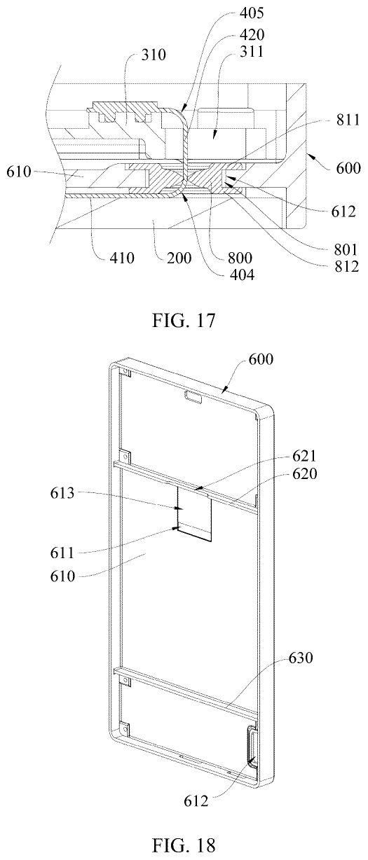

Referring to FIG. 13 and FIG. 17, the connection frame body 600 includes a connection plate 610, and both the second through structure 611 and the third through structure 612 are provided on the connection plate 610. A connection ring 800 is disposed at the third through structure 612, and the connection ring 800 may be specifically made of a material with elasticity, such as rubber. An outer side of the connection ring 800 is connected to the third through structure 612, and an inner side of the connection ring 800 abuts against the flexible printed circuit board 400. Usually, because the terminal device has an insertion/removal structure such as a card tray, there is a risk that liquid and steam are introduced from the insertion/removal structure such as the card tray. In this case, the connection ring 800 can reduce smoothness of flowing of the introduced liquid and the introduced steam along the flexible printed circuit board 400, and alleviate damage to the terminal device caused by the introduced liquid and the introduced steam. Further, the inner side of the connection ring 800 may be set to be in interference fit with the flexible printed circuit board 400, to further improve a blocking capability for the introduced liquid and the introduced steam, and further alleviate damage to the terminal device caused by the introduced liquid and the introduced steam.

Referring to FIG. 17, a first ring plate 811 and a second ring plate 812 are respectively disposed at two ends (upper and lower ends in FIG. 17) on the outer side of the connection ring 800, and two sides of the connection plate 610 respectively abut against the first ring plate 811 and the second ring plate 812. There is a movable gap 801 between a wall surface of the third through structure 612 and a part of the connection ring 800 between the first ring plate 811 and the second ring plate 812, and the movable gap 801 can enable the connection ring 800 to be more smoothly mounted in the third through structure 612. In addition, the third through structure 612 is usually formed in a manner of mechanical processing, injection molding, casting, or the like, and there may be a burr on the wall surface of the third through structure 612. The movable gap 801 can further reduce a possibility of piercing the connection ring 800 by the burr on the wall surface of the third through structure 612, and reduce a failure risk of the connection ring 800.

Referring to FIG. 13 again, the terminal device further includes a communication card mounting portion 500, for example, a corresponding card tray may be disposed. In the second direction, while the second branch 420 is disposed on a side edge of the flexible printed circuit board 400 (for example, disposed on a left side edge in the figure), the communication card mounting portion 500 is disposed on a side of the flexible printed circuit board 400 facing away from the second branch 420 (for example, disposed on a right side in the figure). In this case, the communication card mounting portion 500 is relatively far from the second branch 420 and the corresponding connection ring 800 is relatively far, which helps further reduce smoothness of flowing of the introduced liquid and the introduced steam along the flexible printed circuit board 400, and further alleviate damage to the terminal device caused by the introduced liquid and the introduced steam.

Referring to FIG. 16 and FIG. 18 to FIG. 20, a first vertical plate 620 and a second vertical plate 630 spaced apart from each other are disposed on the second side 602 of the connection plate 610, that is, the first vertical plate 620 and the second vertical plate 630 are in a vertical state relative to the connection plate 610. The first component group 100 is disposed on a side of the first vertical plate 620 facing away from the second vertical plate 630 (for example, disposed on an upper side in FIG. 16), both the battery 700 and the first bonding layer 710 are disposed between the first vertical plate 620 and the second vertical plate 630, and the third component group 300 (including the second circuit board 310) is disposed on a side of the second vertical plate 630 facing away from the first vertical plate 620 (for example, disposed on a lower side in FIG. 16). The second through structure 611 may also be provided between the first vertical plate 620 and the second vertical plate 630 (in this case, a distance from the second through structure 611 to the first vertical plate 620 may be further set to be less than a distance from the second through structure 611 to the second vertical plate 630, that is, the second through structure 611 is closer to the first vertical plate 620). Certainly, the second through structure 611 may alternatively be provided on the side of the first vertical plate 620 facing away from the second vertical plate 630. This is not limited in this embodiment. The third through structure 612 is provided on the side of the second vertical plate 630 facing away from the first vertical plate 620 (for example, provided on a lower side in FIG. 18). Alternatively, the third through structure 612 is provided between the first vertical plate 620 and the second vertical plate 630, and a distance from the third through structure 612 to the second vertical plate 630 is less than a distance from the third through structure 612 to the first vertical plate 620 (that is, the third through structure 612 is closer to the second vertical plate 630). This is not limited in this embodiment.

In addition, referring to FIG. 18 to FIG. 20, while the second through structure 611 is provided between the first vertical plate 620 and the second vertical plate 630, a groove 613 is provided on the connection plate 610, the groove 613 extends in the direction from the first component group 100 to the second component group 200 (in a vertical direction in the figure), and an end portion of the groove 613 is connected to the second through structure 611. In the direction from the first component group 100 to the second component group 200, a part of the flexible printed circuit board 400 is accommodated in the groove 613. The groove 613 can reduce a total thickness of the part of the flexible printed circuit board 400 accommodated in the groove 613 and the connection plate 610, thereby reducing the overall thickness of the terminal device.

To make a connection of a part of the flexible printed circuit board 400 on the second side 602 of the connection frame body 600 more stable, referring to FIG. 16, the terminal device further includes a second bonding layer 720, and the second bonding layer 720 may be set as a back adhesive. The second bonding layer 720 is disposed in the groove 613, and two sides of the second bonding layer 720 are respectively bonded to the flexible printed circuit board 400 and a wall surface of the groove 613. In this case, the second bonding layer 720 is disposed in the groove 613, which also helps reduce the overall thickness of the terminal device by using the groove 613.

Referring to FIG. 16 and FIG. 18 to FIG. 20, a third notch 621 is provided on a side of the first vertical plate 620 facing away from the connection plate 610, and the flexible printed circuit board 400 is at least partially accommodated in the third notch 621 in a thickness direction. The third notch 621 can alleviate scratch damage to the flexible printed circuit board 400, and reduce a stacking thickness of the third notch 621 and the flexible printed circuit board 400, which helps reduce the overall thickness of the terminal device. In addition, a part of the first vertical plate 620 outside the third notch 621 can have a relatively high height, which helps improve structural strength of the first vertical plate 620 and the connection frame body 600.

When the first vertical plate 620 and the second vertical plate 630 are disposed, referring to FIG. 16, a first bent portion 401, a second bent portion 402, and a third bent portion 403 are provided on the flexible printed circuit board 400. The first bent portion 401, the second bent portion 402, and the third bent portion 403 are arranged in the direction from the first component group 100 to the second component group 200. The first bent portion 401 and the second bent portion 402 may be set as L-shaped bends, and the third bent portion 403 may be set as a Z-shaped bend. There is a first included angle between a part (an upper part in FIG. 16) of the flexible printed circuit board 400 on a side of the first bent portion 401 facing away from the second bent portion 402 and a plate plane of the connection plate 610. For example, the first included angle is 0 degrees, and the part is set to be parallel to the plate plane of the connection plate 610 as a whole. There is a second included angle between a plate plane of the first vertical plate 620 and a part of the flexible printed circuit board 400 between the first bent portion 401 and the second bent portion 402. For example, the second included angle is o degrees, and the part is set to be parallel to the plate plane of the first vertical plate 620 as a whole. There is a third included angle between a part of the flexible printed circuit board 400 on a side of the third bent portion 403 facing away from the second bent portion 402 and the plate plane of the connection plate 610. For example, the third included angle is 0 degrees, and the part is set to be parallel to the plate plane of the connection plate 610 as a whole. That is, the first included angle, the second included angle, and the third included angle are set to be greater than or equal to 0 degrees and less than 90 degrees, for example, 0 degrees, 10 degrees, 20 degrees, 45 degrees, or 60 degrees. This is not limited in this embodiment.

Referring to FIG. 17, a fourth bent portion 404 and a fifth bent portion 405 are provided on the flexible printed circuit board 400, and the fourth bent portion 404 and the fifth bent portion 405 may be set as L-shaped bends. Two ends of the fourth bent portion 404 are respectively connected to the main body section 410 and the second branch 420, and the fifth bent portion 405 is provided on the second branch 420. There is a fourth included angle between a plate plane of the second vertical plate 630 and a part of the second branch 420 between the fourth bent portion 404 and the fifth bent portion 405. For example, the fourth included angle is 0 degrees, and the part is set to be parallel to the plate plane of the second vertical plate 630 as a whole. There is a fifth included angle between a part (an upper part in FIG. 17) of the second branch 420 on a side of the fifth bent portion 405 facing away from the fourth bent portion 404 and the plate plane of the connection plate 610. For example, the fifth included angle is 0 degrees, and the part is set to be parallel to the plate plane of the connection plate 610 as a whole. That is, both the fourth included angle and the fifth included angle are set to be greater than or equal to 0 degrees and less than 90 degrees, for example, 0 degrees, 10 degrees, 20 degrees, 45 degrees, or 60 degrees. This is not limited in this embodiment.

Referring to FIG. 21, a fourth notch 311 is provided on an edge of the second circuit board 310, and the second branch 420 passes through the fourth notch 311 to be connected to the second circuit board 310, to improve the overall compactness of the terminal device.

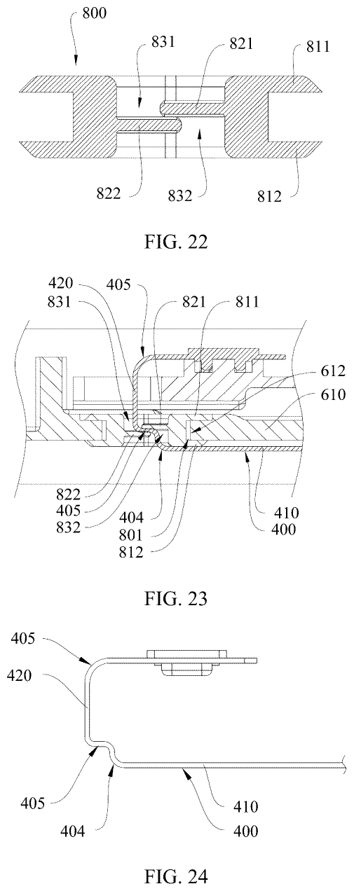

For the foregoing two implementations, referring to FIG. 22 and FIG. 23, the connection ring 800 has the following optional improvement manners.

Referring to FIG. 22 and FIG. 23, a first rib plate 821 is disposed on one side of an inner side surface of the connection ring 800, and a second rib plate 822 is disposed on the other side of the inner side surface of the connection ring 800. A projection of the first rib plate 821 and a projection of the second rib plate 822 at least partially overlap in an axial direction (a vertical direction in the figure) of the connection ring 800, and two sides of the flexible printed circuit board 400 respectively abut against the first rib plate 821 and the second rib plate 822. In this case, the first rib plate 821 and the second rib plate 822 can further block the introduced liquid and the introduced steam flowing along the flexible printed circuit board 400, which helps further alleviate damage to the terminal device caused by the introduced liquid and the introduced steam.

In addition, referring to FIG. 23 and FIG. 24, the flexible printed circuit board 400 has a sixth bent portion 406, and the sixth bent portion 406 may be set as a Z-shaped bend. A sixth included angle is set between each of parts of the flexible printed circuit board 400 on two sides of the sixth bent portion 406 and the axial direction of the connection ring 800. For example, the sixth included angle is 0 degrees, and the part is set to be parallel to the axial direction of the connection ring 800 as a whole. That is, the sixth included angle is greater than or equal to 0 degrees and less than 90 degrees, for example, 0 degrees, 10 degrees, 20 degrees, 45 degrees, or 60 degrees. This is not limited in this embodiment. The parts of the flexible printed circuit board 400 on the two sides of the sixth bent portion 406 are respectively configured to abut against an end portion of the first rib plate 821 and an end portion of the second rib plate 822. In this case, the first rib plate 821 and the second rib plate 822 whose projections at least partially overlap can reduce a redundant length of the flexible printed circuit board 400, to improve neatness of an internal structure of the terminal device, and reduce assembling interference of the flexible printed circuit board 400 to another component. The parts of the flexible printed circuit board 400 on the two sides of the sixth bent portion 406 are respectively configured to abut against the end portion of the first rib plate 821 and the end portion of the second rib plate 822, which can reduce a shaking degree of the flexible printed circuit board 400 at this location.

Further, in an optional implementation, referring to FIG. 22 and FIG. 23, there is a first accommodating gap 831 between the end portion of the first rib plate 821 and the inner side surface of the connection ring 800, a width of the first accommodating gap 831 is set in a direction (a horizontal direction in the figure) in which the end portion of the first rib plate 821, the flexible printed circuit board 400, and the inner side surface of the connection ring 800 are sequentially arranged, and the width of the first accommodating gap 831 is greater than or equal to a thickness of the flexible printed circuit board 400. There is a second accommodating gap 832 between the end portion of the second rib plate 822 and the inner side surface of the connection ring 800, a width of the second accommodating gap 832 is set in a direction (the horizontal direction in the figure) in which the end portion of the second rib plate 822, the flexible printed circuit board 400, and the inner side surface of the connection ring 800 are sequentially arranged, and the width of the second accommodating gap 832 is greater than or equal to the thickness of the flexible printed circuit board 400. In this case, when the width of the first accommodating gap 831 is equal to the thickness of the flexible printed circuit board 400, and the width of the second accommodating gap 832 is equal to the thickness of the flexible printed circuit board 400, a shaking degree of the flexible printed circuit board 400 at this location can be further reduced. When the width of the first accommodating gap 831 is greater than the thickness of the flexible printed circuit board 400, and the width of the second accommodating gap 832 is greater than the thickness of the flexible printed circuit board 400, the first accommodating gap 831 and the second accommodating gap 832 can further consume the redundant length of the flexible printed circuit board 400, further improve neatness of the internal structure of the terminal device, and further reduce assembling interference of the flexible printed circuit board 400 to the another component.

Certainly, the connection ring 800 may alternatively be disposed at the second through structure 611 in the foregoing manner, including a connection relationship of providing a movable gap between a wall surface of the second through structure 611 and the part of the connection ring 800 between the first ring plate 811 and the second ring plate 812, and the like. This is not limited in this embodiment.

The foregoing descriptions are merely specific implementations of this application, and any change or replacement readily figured out by a person skilled in the art within the technical scope disclosed in this application shall fall within the protection scope of this application. The protection scope of this application shall be subject to the protection scope of the claims.

1. A terminal device, wherein the terminal device comprises:
a first component group, wherein the first component group comprises a first circuit board, and at least one selected from a processor chip, a baseband chip, a radio frequency assembly, and a camera assembly is disposed on the first circuit board;
a flexible printed circuit board, wherein one end of the flexible printed circuit board is connected to the first circuit board, and a first branch and a second branch are disposed on the other end of the flexible printed circuit board;
a second component group, wherein the second component group is electrically connected to the first branch; and
a third component group, wherein the third component group is electrically connected to the second branch.

2. The terminal device according to claim 1, wherein the two ends of the flexible printed circuit board are respectively connected to the first component group and the second component group, and the first branch is disposed on an end portion of the flexible printed circuit board facing away from the first component group; the terminal device has a first direction and a second direction, the first direction is set as a direction from the first component group to the second component group, the first direction intersects the second direction, and the second direction is set to be parallel to a plane of the flexible printed circuit board; and in the second direction, the second branch is disposed between two side edges of the flexible printed circuit board or the second branch is disposed on a side edge of the flexible printed circuit board.

3. The terminal device according to claim 2, wherein a first through structure is provided on the flexible printed circuit board, and the second branch is disposed on a sidewall of the first through structure.

4. The terminal device according to claim 3, wherein when the second branch is disposed between the two side edges of the flexible printed circuit board in the second direction, the first through structure is set as a through hole; or when the second branch is disposed on the side edge of the flexible printed circuit board, the first through structure is set as a first notch.

5. The terminal device according to claim 2, wherein the terminal device further comprises a communication card mounting portion; and when the second branch is disposed on the side edge of the flexible printed circuit board in the second direction, the communication card mounting portion is disposed on a side of the flexible printed circuit board facing away from the second branch.

6. The terminal device according to claim 1, wherein the terminal device further comprises a connection frame body, and the connection frame body has a first side and a second side that are provided opposite to each other; the second component group is disposed on the first side, and both the first component group and the third component group are disposed on the second side; and a second through structure and a third through structure are provided on the connection frame body, one end of the flexible printed circuit board passes through the second through structure from the first side to be electrically connected to the first component group, and the second branch passes through the third through structure from the first side to be electrically connected to the third component group.

7. The terminal device according to claim 6, wherein the terminal device further comprises a battery and a first bonding layer, and the battery is disposed on the second side; the first component group is spaced apart from the third component group, and both the battery and the first bonding layer are disposed between the first component group and the third component group; the first bonding layer is disposed between the battery and the connection frame body, and two sides of the first bonding layer are respectively bonded to the battery and the connection frame body; and a second notch is provided on a side of the first bonding layer facing the first component group, and the second notch communicates with the second through structure.

8. The terminal device according to claim 7, wherein the connection frame body comprises a connection plate, and a first vertical plate and a second vertical plate spaced apart from each other are disposed on a second side of the connection plate; the first component group is disposed on a side of the first vertical plate facing away from the second vertical plate, both the battery and the first bonding layer are disposed between the first vertical plate and the second vertical plate, and the third component group is disposed on a side of the second vertical plate facing away from the first vertical plate; and the second through structure is provided on the connection plate, and the second through structure is provided between the first vertical plate and the second vertical plate, or the second through structure is provided on the side of the first vertical plate facing away from the second vertical plate.

9. The terminal device according to claim 8, wherein when the second through structure is provided between the first vertical plate and the second vertical plate, a distance from the second through structure to the first vertical plate is less than a distance from the second through structure to the second vertical plate.

10. The terminal device according to claim 7, wherein when the second through structure is provided between the first vertical plate and the second vertical plate, a groove is provided on the connection plate, the groove extends in the direction from the first component group to the second component group, and an end portion of the groove is connected to the second through structure; and in the direction from the first component group to the second component group, a part of the flexible printed circuit board is accommodated in the groove.

11. The terminal device according to claim 10, wherein the terminal device further comprises a second bonding layer, the second bonding layer is disposed in the groove, and two sides of the second bonding layer are respectively bonded to the flexible printed circuit board and a wall surface of the groove.

12. The terminal device according to claim 7, wherein a third notch is provided on a side of the first vertical plate facing away from the connection plate, and the flexible printed circuit board is at least partially accommodated in the third notch in a thickness direction; or
a first bent portion, a second bent portion, and a third bent portion are provided on the flexible printed circuit board, and the first bent portion, the second bent portion, and the third bent portion are arranged in the direction from the first component group to the second component group; and there is a first included angle between a part of the flexible printed circuit board on a side of the first bent portion facing away from the second bent portion and a plate plane of the connection plate, there is a second included angle between a plate plane of the first vertical plate and a part of the flexible printed circuit board between the first bent portion and the second bent portion, there is a third included angle between a part of the flexible printed circuit board on a side of the third bent portion facing away from the second bent portion and the plate plane of the connection plate, and the first included angle, the second included angle, and the third included angle are all set to be greater than or equal to 0 degrees and less than 90 degrees.

13. (canceled)

14. The terminal device according to claim 7, wherein the flexible printed circuit board comprises a main body section, two ends of the main body section are respectively connected to the first component group and the second component group, and the first branch is disposed on an end portion of the main body section facing away from the first component group; and the third through structure is provided on the connection plate, and the third through structure is provided on a side of the second vertical plate facing away from the first vertical plate, or the third through structure is provided between the first vertical plate and the second vertical plate, and a distance from the third through structure to the second vertical plate is less than a distance from the third through structure to the first vertical plate.

15. The terminal device according to claim 14, wherein a fourth bent portion and a fifth bent portion are provided on the flexible printed circuit board, two ends of the fourth bent portion are respectively connected to the main body section and the second branch, and the fifth bent portion is provided on the second branch; and there is a fourth included angle between a plate plane of the second vertical plate and a part of the second branch between the fourth bent portion and the fifth bent portion, there is a fifth included angle between a part of the second branch on a side of the fifth bent portion facing away from the fourth bent portion and a plate plane of the connection plate, and both the fourth included angle and the fifth included angle are set to be greater than or equal to 0 degrees and less than 90 degrees.

16. The terminal device according to claim 15, wherein the third component group comprises a second circuit board; and when the third through structure is provided on the side of the second vertical plate facing away from the first vertical plate, a fourth notch is provided on an edge of the second circuit board, and the second branch passes through the fourth notch to be connected to the second circuit board.

17. The terminal device according to claim 6, wherein a connection ring is disposed at the second through structure or the third through structure, an outer side of the connection ring is connected to the second through structure or the third through structure, and an inner side of the connection ring abuts against the flexible printed circuit board.

18. The terminal device according to claim 17, wherein the connection frame body comprises a connection plate, and both the second through structure and the third through structure are provided on the connection plate; and a first ring plate and a second ring plate are respectively disposed at two ends of the outer side of the connection ring, two sides of the connection plate respectively abut against the first ring plate and the second ring plate, and there is a movable gap between a wall surface of the second through structure or a wall surface of the third through structure and a part of the connection ring between the first ring plate and the second ring plate.

19. The terminal device according to claim 17, wherein a first rib plate is disposed on one side of an inner side surface of the connection ring, and a second rib plate is disposed on the other side of the inner side surface of the connection ring; and in an axial direction of the connection ring, a projection of the first rib plate and a projection of the second rib plate at least partially overlap, and two sides of the flexible printed circuit board respectively abut against the first rib plate and the second rib plate.

20. The terminal device according to claim 19, wherein the flexible printed circuit board has a sixth bent portion, a sixth included angle is set between each of parts of the flexible printed circuit board on two sides of the sixth bent portion and the axial direction of the connection ring, and the sixth included angle is greater than or equal to 0 degrees and less than 90 degrees; and the parts of the flexible printed circuit board on the two sides of the sixth bent portion are respectively configured to abut against an end portion of the first rib plate and an end portion of the second rib plate.

21. The terminal device according to claim 19, wherein there is a first accommodating gap between an end portion of the first rib plate and the inner side surface of the connection ring, a width of the first accommodating gap is set in a direction in which the end portion of the first rib plate, the flexible printed circuit board, and the inner side surface of the connection ring are sequentially arranged, and the width of the first accommodating gap is greater than or equal to a thickness of the flexible printed circuit board; and/or there is a second accommodating gap between an end portion of the second rib plate and the inner side surface of the connection ring, a width of the second accommodating gap is set in a direction in which the end portion of the second rib plate, the flexible printed circuit board, and the inner side surface of the connection ring are sequentially arranged, and the width of the second accommodating gap is greater than or equal to the thickness of the flexible printed circuit board.

22. (canceled)
